(19) United States
(12) Patent Application Publication
(10) Pub. No.: US 2026/0303119 A1
(43) Pub. Date: Oct. 1, 2026

(54) VARIABLE LENGTH ENCODING FOR ML MATRICES

(71) Applicant: Advanced Micro Devices, Inc., Santa Clara, CA (US)

(72) Inventor: Holger Heinrich GRUEN, Peissenberg (DE)

(21) Appl. No.: 19/093,061

(22) Filed: Mar. 27, 2025

(51) Int. Cl. H03M 7/40; H03M 7/30

(52) U.S. Cl. CPC H03M 7/4093; H03M 7/6011; H03M 7/6058

(57) ABSTRACT

Embodiments herein relate to storing the bit widths of values of matrices associated with an ML model, including quantized matrices, in a header. In the header, each number of bits included in a matrix is represented by an encoded value, and the encoded value is stored in a header. Different bits can be represented by a different encoded value, where each encoded value occupies the same amount of bits.

### TECHNICAL FIELD

The following relates to machine learning (ML), more specifically, to matrices found in ML models.

### BACKGROUND

In ML models, saved matrices can be numerical arrays that store learned parameters, weights, biases, embeddings, or other data used by the model for making predictions. These matrices can be saved after training to allow the model to be reloaded and used without being retrained. Saved matrices can contain a varying number of values, and use a varying amount of memory when the ML model is deployed on a hardware device.

### SUMMARY

According to some embodiments, a computing system including: a processor; and memory including: a matrix associated with an ML (machine learning) model, where the matrix includes at least two entries, where the at least two entries store a different number of bits; and a block header for the matrix that stores encoded values for representing bit widths of the at least two entries, where the encoded values are different.

According to other embodiments, a method including: receiving a matrix associated with an ML (machine learning) model, where the matrix includes at least two entries, where the at least two entries store a different number of bits; assigning encoded values to the at least two entries based on the number of bits, where the encoded values are different; and generating a block header for the matrix that stores the encoded values.

According to other embodiments, a computer-readable storage medium having computer-readable program code embodied therewith, the computer-readable program code executable by one or more computer processors to perform operations, the operations including:

receiving a matrix associated with an ML (machine learning) model, where the matrix comprises at least two entries, where the at least two entries store a different number of bits; assigning encoded values to the at least two entries based on the number of bits, where the encoded values are different; and generating a block header for the matrix that stores the encoded values.

### BRIEF DESCRIPTION OF DRAWINGS

FIG. 1 illustrates a header generator, according to some embodiments.

FIG. 2 illustrates an example of an encoding for a matrix, according to some embodiments.

FIG. 3 illustrates a flow diagram for generating a header, according to some embodiments.

FIG. 4 illustrates an example showing where the header resides in memory, according to some embodiments.

FIG. 5 illustrates a flow diagram for looking up the block header in memory, according to some embodiments.

FIG. 6a illustrates an example of looking up the block header in memory, according to some embodiments.

FIG. 6b illustrates an example of looking up the block header in memory, according to some embodiments.

### DETAILED DESCRIPTION

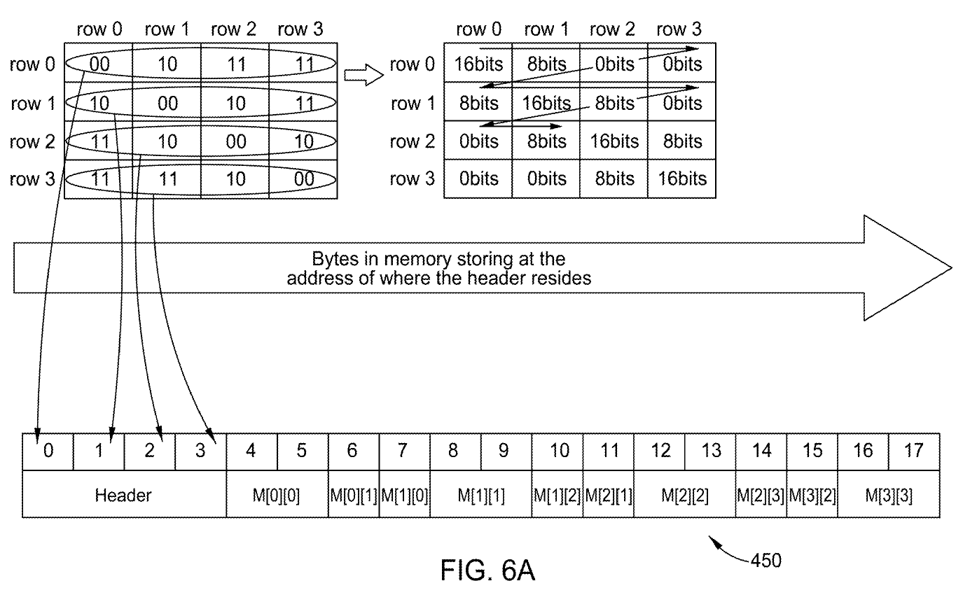

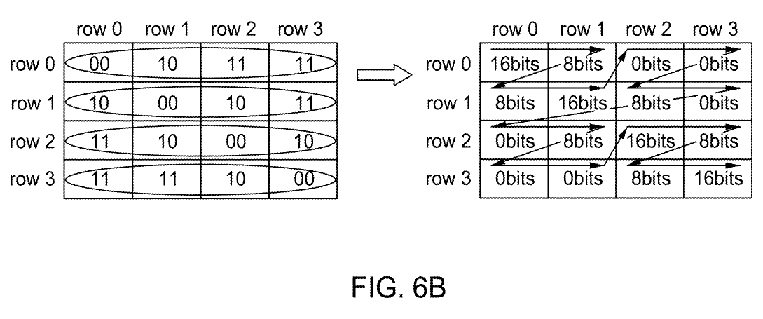

Embodiments herein relate to generating a header for a matrix or matrices of an ML model. After an ML model is trained, and the matrices within the model have been saved, the matrices occupy memory on hardware that the model has been deployed on. Matrices can be quantized so that the storage used by the values in the matrix are reduced. However, quantized matrices still use a relatively large amount of storage. Embodiments herein relate to storing the values of matrices associated with an ML model using variable bit-width values, including quantized values, in a memory segment that is addressed through a header. For example, if four different bit-widths can be used to for storing the values of entries of a matrix, the header can then stores 2 bits for each entry of the matrix to be able to identify what bit-width is used at each matrix entry. . For example, if the matrix contains values that take up 0 bits (this stands for an entry with the value 0), four bit wide values, values that take up eight bits, and values that take up sixteen bits, the header can encode the values that take up four bits as the two bit value “00”, values that take up eight bits as the two bit value “01,” values that take up sixteen bits as the two bit value “10”and, the two bit value “11” for an entry of value 0. Each represented bit width is encoded in the header with the same of bits, (e.g. 2) . Each entry of the matrix addressed through the header entries can be looked-up in memory, as the address of the matrix entry can be calculated based on where the 2 bits entry, that encodes its bit-width, sits in the header. Examples of this process are provided in FIG. 6. Generating a header for the matrices of an ML model saves even more memory, offering improvements in efficiency, a greater variety of hardware where the ML model can be deployed, among other advantages.

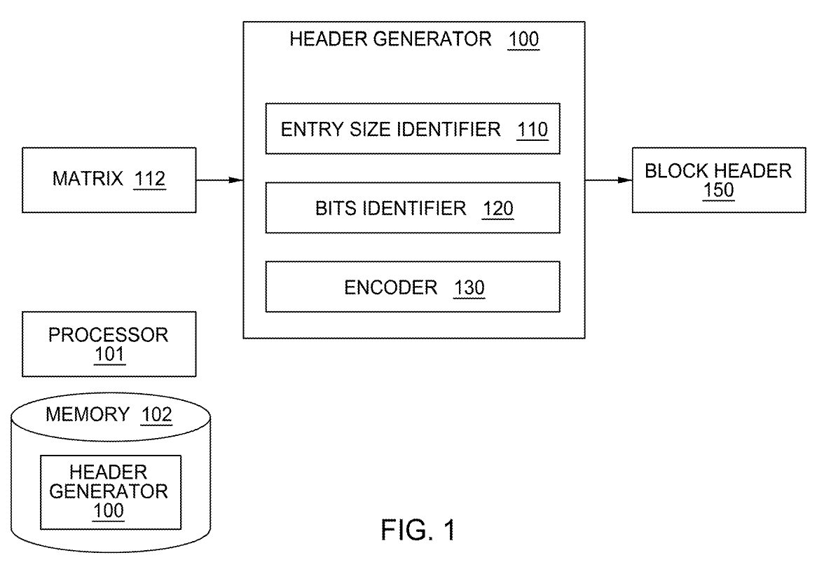

FIG. 1 illustrates the header generator 100 generating a block header 150 for the matrices of an ML model. The ML model can be a trained ML model.

The header generator 100 can be implemented on a computing system with a processor 101, and a memory 102. The processor 101 generally retrieves and executes programming instructions stored in the memory 102. The processor 101 is representative of a single central processing unit (CPU), multiple CPUs, a single CPU having multiple processing cores, graphics processing units (GPUs) having multiple execution paths, specialized AI hardware accelerators (e.g., systems of a chip), and the like.

A CPU can handle tasks that use lower parallelism such as managing the overall workflow, such as loading models, initiating test cases, and delegating tasks to a GPU.

The memory 102 generally includes program code for performing various functions related to use of the header generator 100. The program code is generally described as various functional “applications” or “modules” within the memory 102, although alternate implementations may have different functions and/or combinations of functions. Within the memory 102, the header generator 100 facilitates generating a block header 150 that represents the entries of a matrix 112, discussed in further detail below.

The header generator 100 receives a matrix 112. The matrix 112 is associated with an ML model, and can be a weight matrix, or a quantized weight matrix that stores learned parameters between layers of a neural network ML model, a bias matrix, which includes offset values to adjust activations, an embedding matrix, which maps categorical variables such as words in natural language processing (NLP) to continuous vector spaces, a covariance matrix, which is used in probabilistic ML models to capture relationships between feature, among other types of matrices.

The entry size identifier 110 determines how many entries exist in the matrix. Entries can include data entries (e.g. an INT8 data entry, an INT16 data entry, an FP8 data entry, etc.). The entry size identifier 110 can count the rows and columns of the matrix to determine how many entries are within the matrix 112.

Once the size of the matrix 112 is determined, the bits identifier 120 determines the variety of bit widths supported by the entries of the matrix. For example, if there are some entries of two bit widths, others of four bit widths, and others of eight bit widths, the matrix supports three different bit widths – two, four and eight. After this is established, the encoder 130 generates values to represent the different bit widths supported by the matrix. For example, the encoder can establish that two bit widths should be represented by the two bit value “00”, four bits should be represented by the two bit value “01,” and eight bits should be represented by the two bit value “10.” The encoding is not limited to a two bit encoding. For example, if the matrix stores data entries that have more than four different bit widths, then the encode may use three (or more) bits to represent the different bit widths.

Once the encoding has been established, the header generator 100 outputs the block header 150, which is a table like structure containing the encodings for each of the entries of the matrix 112. The block header saves memory by representing the varying amount of memory occupied by each entry of the matrix as encoded values, where each encoded value is a constant bit with, holistically reducing the space occupied by the matrix 112 itself.

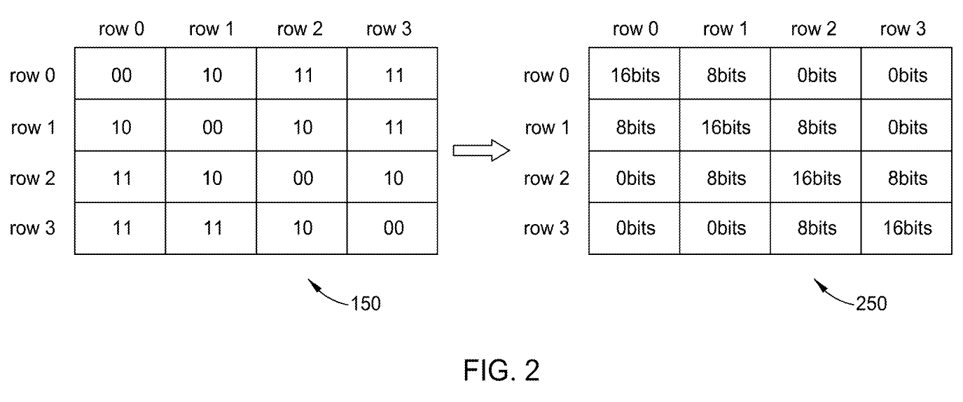

FIG. 2 illustrates an example of the block header 150, and the encoded values represented within the matrix 250. As shown, the original matrix 112 received by the header generator 100 supports three different bits. The bits identifier 120 identifies the matrix 112 supporting the three different bit widths. The matrix 112 contains values that occupy sixteen bits, eight bits, and zero bits. This is shown by the pre-encoded matrix 250. In this example, the encoder 130 encodes the values representing sixteen bits as the two bit value “00,” the values representing the eight bit values as “10”, and values representing zero bits as “11.” Thus, the header 150 includes a one-to-one relationship between its encoded values and the data entries in the matrix 250. The header 150 stores “00” for every corresponding location in the matrix 250 that includes a 16 bit entry, “10” for every corresponding location in the matrix 250 that includes an 8 bit entry, and so forth. The header 150 contains thirty-two header bits per entry of the matrix, and the header 150 is displayed in a four by four matrix, as illustrated.

This scheme enables the matrix 250 to include data entries of varying bit widths, instead of being limited to a single bit width. For example, with typical matrices, each entry must have the same bit width so the matrix can be parsed correctly (e.g., so the hardware knows where the next data entry begins). However, as shown in the matrix 250 many of the entries are a value of 0, which would still require 16 bits (e.g., 16 zeros) in a typical matrix. However, with this scheme, the matrix 250 does not have to store any bits for 0 values, and instead this is tracked by the encoded values in the header 150, thereby achieving a net savings of 14 bits. This scheme also saves bits for the 8 bit entries. With a typical matrix, 16 bits would still be used to represent these 8 bit value. However, in FIG. 2, the matrix 250 can store only the 8 bits, thereby achieving a net savings of 6 bits. Thus, the hardware can use the encoded values in the header 150 to determine where the next data entries in the matrix 250 begins since many of these values have different bit widths.

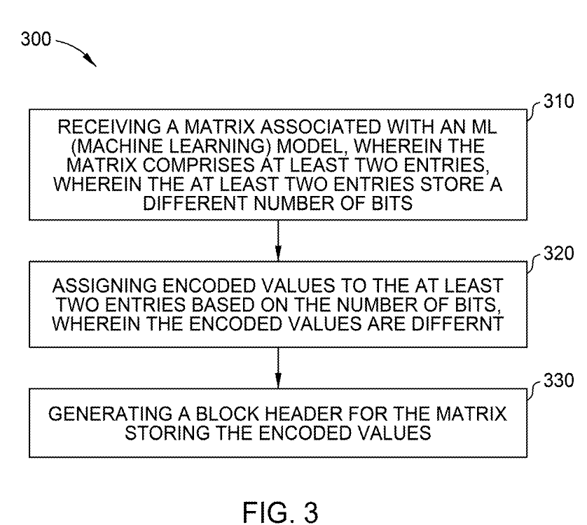

FIG. 3 illustrates a flow diagram 300 for generating the block header 150.

At block 310 the header generator 100 receives the matrix 112. The matrix 112 is associated with an ML model, and the matrix includes at least two entries. The two entries are separate and can store a different number of bits, as discussed in FIG. 1. Also as discussed in FIG. 1, the matrix 112 can be of varying types and sizes. Additionally, the matrix 112 can support multiple different bit widths in each of its entries.

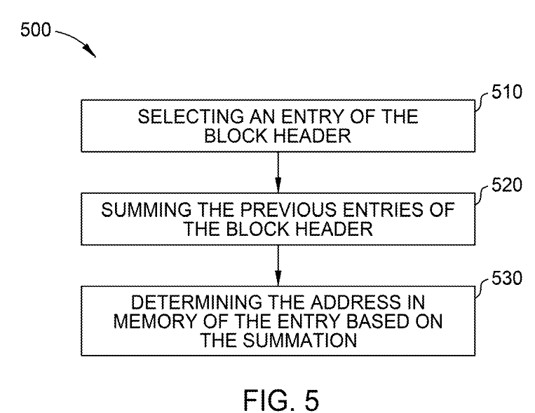

At block 320, the encoder 130 uses the information extracted from the entry size identifier 110 and the bits identifier 120 to assign encoded values to the entries of the matrix 112. As discussed in FIGS. 1 and 2, a certain encoded value is assigned to represent a certain bit value represented in the matrix, and different bit sizes are represented by different encoded values. This helps organize the header to accurately represent the entries of the matrix 112, and it allows the lookup process, which is discussed in FIG. 5, to run smoothly.

At block 330 the header generator 100 generates the block header 150. The block header stores the encoded values representing entries of the matrix 112. The header can be various forms, such as the four by four matrix illustrated in FIG. 2, and the form can also depend on the dimensions of the matrix 112. The block header 150 stores the encoded values representing entries of the matrix 112 in such a way that the matrix entries’ address in memory can be looked up using the header. This look-up process is illustrated in FIGS. 6a and 6b.

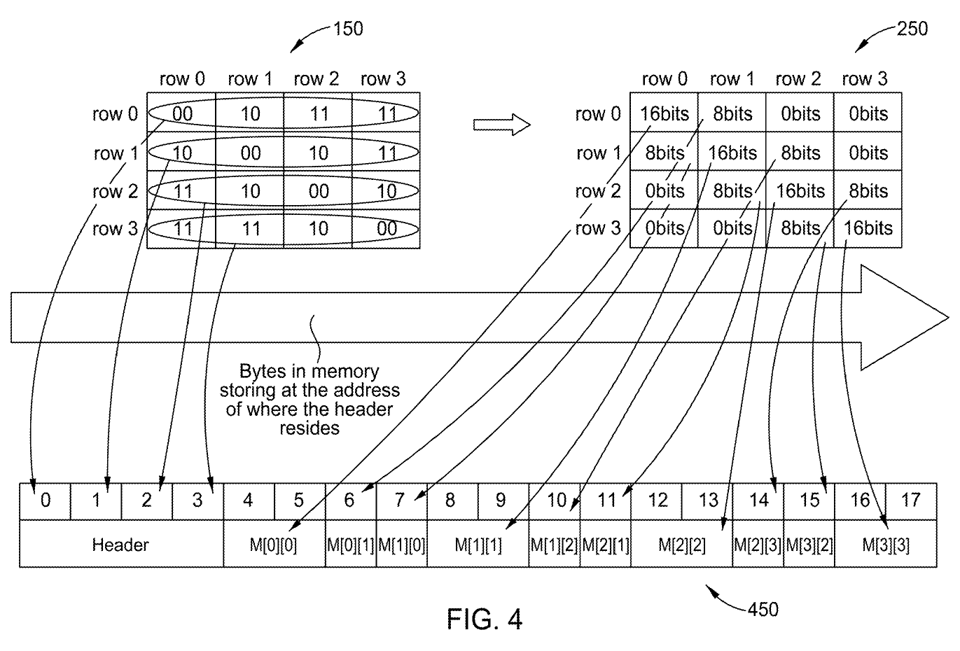

FIG. 4 illustrates a where the header resides in memory 450. The addresses in memory 450 indicate that the example header 150 can be stored in eighteen bytes.

The encoded header 150 is similar to the header 150 illustrated in FIG. 2, where the encoder 130 encodes the values representing sixteen bits as the two bit value “00,” the values representing the eight bit values as “10”, and values representing zero bits as “11.” The header 150 contains thirty-two bits total, with two bits per entry of the matrix, and the header 150 is displayed in a four by four matrix.

The encoded values are two bit values that encode a variety of values spanning different bit sizes. Without having to store each of the many different supported bit sizes, the header representing an entry of the matrix 112 can still be easily found at an address 450 in memory. Different strategies can be employed to find the entry in memory, as shown in FIGS. 6a and 6b. As illustrated in FIG. 4, the bytes of memory start at the address 450 where the header resides.

FIG. 5 illustrates a flow diagram 500 for finding an address in memory of an entry of the matrix 112.

At block 510, an entity selects an entry in the block header for which the entity wishes to find an address in memory for. The entity can be a software program, a user, a component within the ML model or hardware, among other things. An entry in the block header is depicted in FIG. 2, as a point where a row and column meet.

At block 520, the entity sums the previous entries of the block header. For example. If the entry selected for a memory address lookup is found on the third row of the first column, the previous entries of the header can be de-coded such that the values they are encoded for are represented, and decoded values can be added. At block 530, the address in memory based on the summation is determined. After adding those previous values, the address in memory of the matrix entry can be found. The pattern of summing the previous values can vary. Examples of this summation and look up is depicted in FIGS. 6a and 6b.

FIG. 6a illustrates one example flow for using the block header to look up the address in memory of where an entry of the matrix resides. The memory block with the values of the matrix does not need to sit directly behind the header, but could be placed in other known memory locations.

In FIG. 6a, the summation pattern is from right to left, as depicted by the arrows in the illustration.

In this example, the location of the entry M[2][2] is computed. First, it is noted that M[2][2] is encoded as 00, meaning it occupies 16 bits of storage. As illustrated, the previous bits’ decoded values are summed, so sixteen is added to eight, is added to zero, is added to zero, is added to eight, is added to sixteen, is added to eight, is added to zero, is added to zero is added to eight, is added to sixteen, which equals sixty-four. The header 150 itself occupies a certain number of bits. The number of bits the header 150 occupies can vary. In this illustrated example, the header occupies four bytes of memory, which is the equivalent of thirty-two bits. Thirty-two added to the computed sixty-four equals ninety-six. Ninety-six bites is the equivalent of twelve bytes, which points to the location of M[2][2] at the address 450 of the twelfth byte of memory.

FIG. 6b another example flow for using the block header to look up the address in memory of where an entry of the block resides.

Here, the location of M[2][2] is the same as illustrated in FIG. 6a. However, the summation pattern is slightly different. As shown, a different arrow should be followed to get to M[2][2], meaning the summed values would be sixteen, summed with eight, summed with eight, summed with sixteen, summed with eight, summed with eight. The result is still sixty-four bits, added with the thirty-two bits that represent the header 150 itself, which is ninety-six bits. M[2][2] in this example is still at byte twelve in memory, but the way it was calculated was slightly different than in the way it was calculated in FIG. 6a.

The summation patterns are not limited to the examples shown in FIGS. 6a and 6b. The summation can be performed in a predetermined pattern, or a randomized pattern, among other implementations.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the "C" programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A computing system comprising:
a processor; and
memory comprising:
a matrix associated with an ML (machine learning) model, wherein the matrix comprises at least two entries, wherein the at least two entries store a different number of bits; and
a block header for the matrix that stores encoded values for representing bit widths of the at least two entries, wherein the encoded values are different.

2. The computing system of claim 1, wherein the matrix comprises at least three entries, wherein a first entry and a second entry store a same number of bits, and wherein a third entry stores a number of bits different than the second entry and different than the first entry.

3. The computing system of claim 2 wherein the block header stores two copies of a first encoded value to represent the first entry and the second entry, and
a second, different encoded value, to represent the third entry.

4. The computing system of claim 1 further comprising:
an address in memory of one of the at least two entries based on the block header, wherein determining the address comprises:
selecting an entry of the block header;
summing previous entries of the block header; and
determining the address in memory of the entry based on the summation.

5. The computing system of claim 4, wherein summing the previous entries comprises summing the previous at least two entries from left to right.

6. The computing system of claim 4 wherein summing the previous entries comprises summing the previous at least two entries in a randomized pattern.

7. The computing system of claim 1, wherein each of the encoded values occupies the same amount of memory.

8. The computing system of claim 1, wherein the ML model is a trained ML model.

9. The computing system of claim 8, wherein the matrix is a quantized weight matrix from the trained ML model.

10. The computing system of claim 1, wherein the matrix comprises at least three entries, wherein a first entry, a second entry, and a third entry each store a different number of bits, the computing system further comprising:
a first encoded value to the first entry, a second encoded value to the second entry, and a third encoded value to the third entry, wherein the first, second, and third encoded values are all different.

11. A method comprising:
receiving a matrix associated with an ML (machine learning) model, wherein the matrix comprises at least two entries, wherein the at least two entries store a different number of bits;
assigning encoded values to the at least two entries based on the number of bits, wherein the encoded values are different; and
generating a block header for the matrix that stores the encoded values.

12. The method of claim 11, wherein the matrix comprises at least three entries, wherein a first entry and a second entry store a same number of bits, and wherein a third entry stores a number of bits different than the second entry and different than the first entry.

13. The method of claim 12 further comprising:
assigning a first encoded value to the first entry and the second entry; and
assigning a second, different encoded value, to the third entry.

14. The method of claim 11 further comprising:
determining, based on the block header, an address in memory of one of the at least two entries, wherein determining the address comprises:
selecting an entry of the block header;
summing previous entries of the block header; and
determining the address in memory of the entry based on the summation.

15. The method of claim 14, wherein summing the previous entries comprises summing the previous at least two entries from left to right.

16. The method of claim 14 wherein summing the previous entries comprises summing the previous at least two entries in a randomized pattern.

17. The method of claim 11, wherein each of the encoded values occupies the same amount of memory.

18. The method of claim 11, wherein the ML model is a trained ML model.

19. The method of claim 11, wherein the matrix comprises at least three entries, wherein a first entry, a second entry, and a third entry each store a different number of bits, the method further comprising:
assigning a first encoded value to the first entry, a second encoded value to the second entry, and a third encoded value to the third entry, wherein the first, second, and third encoded values are all different.

20. A computer-readable storage medium having computer-readable program code embodied therewith, the computer-readable program code executable by one or more computer processors to perform operations, the operations comprising:
receiving a matrix associated with an ML (machine learning) model, wherein the matrix comprises at least two entries, wherein the at least two entries store a different number of bits;
assigning encoded values to the at least two entries based on the number of bits, wherein the encoded values are different; and
generating a block header for the matrix that stores the encoded values.
